(19) United States
(12) Patent Application Publication
(10) Pub. No.: US 2020/0388495 A1
(43) Pub. Date: Dec. 10, 2020

(54) LASER IRRADIATION DEVICE, PROJECTION MASK AND LASER IRRADIATION METHOD

(71) Applicant: V Technology Co., Ltd., Yokohama-shi (JP)

(72) Inventor: Michinobu Mizumura, Yokohama-shi (JP)

(21) Appl. No.: 16/763,082

(22) PCT Filed: Dec. 26, 2018
(86) PCT No.: PCT/JP2018/047788

§ 371 Date: May 11, 2020

(30) Foreign Application Priority Data
Jan. 24, 2018 (JP) 2018-010031

(51) Int. Cl. H01L 21/268; H01L 29/786; H01L 21/768; H01L 21/02

(52) U.S. Cl. CPC H01L 21/268; H01L 21/0268; H01L 21/76868; H01L 29/786

(57) ABSTRACT

A laser irradiation device includes a light source that generates laser light; a projection lens that radiates the laser light to a predetermined region of an amorphous silicon thin film deposited on a thin film transistor; and a projection mask including a plurality of opening portions disposed on the projection lens and through which the laser light passes, wherein a predetermined pattern that is able to reduce diffraction of the laser light is formed at a peripheral edge portion of each of the plurality of opening portions.

### TECHNICAL FIELD

This disclosure relates to formation of a thin film transistor and, more particularly, a laser irradiation device, a projection mask and a laser irradiation method that radiate laser light onto an amorphous silicon thin film coated on a substrate and form a polysilicon thin film.

### BACKGROUND

As a thin film transistor having an inverted staggered structure, there is a thin film transistor in which an amorphous silicon thin film is used for a channel region. However, since the amorphous silicon thin film has low electron mobility when the amorphous silicon thin film is used for a channel region, there is a problem that the mobility of charge in the thin film transistor is reduced.

Therefore, there is a technique in which a predetermined region of an amorphous silicon thin film is polycrystallized by being instantaneously heated with laser light, a polysilicon thin film having high electron mobility is formed, and the polysilicon thin film is used for a channel region.

For example, Japanese Unexamined Patent Application Publication No. 2016-100537 discloses that an amorphous silicon thin film is formed on a channel region, and then a process in which the amorphous silicon thin film is laser-annealed by being irradiated with laser light such as an excimer laser and the polysilicon thin film is crystallized due to melting and solidifying in a short time is performed. JP '537 discloses that, due to the process being performed, a channel region between a source and a drain of a thin film transistor can be formed as a polysilicon thin film having high electron mobility, and an operational speed of the transistor can be increased.

In the thin film transistor described in JP '537, although laser annealing is performed by irradiating the channel region between the source and the drain with the laser light, the intensity of the radiated laser light may not be constant, and a degree of crystallization of the polysilicon crystal may become non-uniform in the channel region. In particular, when the laser light is radiated through a projection mask, the intensity of the laser light radiated to the channel region may not be constant due to a shape of the projection mask and, as a result, the degree of crystallization in the channel region may become non-uniform.

Accordingly, characteristics of the formed polysilicon thin film may not be uniform, and non-uniformity in the characteristics of the individual thin film transistors included in the glass substrate may be caused. As a result, there is a problem that display unevenness occurs in a liquid crystal formed using the glass substrate.

It could therefore be helpful to provide a laser irradiation device, a projection mask and a laser irradiation method that are able to suppress variation in characteristics in a plurality of thin film transistors included in a substrate by reducing non-uniformity in characteristics of laser light applied to a channel region and reducing variation in a formed polysilicon thin film.

### SUMMARY

We thus provide:

A laser irradiation device includes a light source that generates laser light, a projection lens that radiates the laser light to a predetermined region of the amorphous silicon thin film deposited on a thin film transistor, and a projection mask including a plurality of opening portions disposed on the projection lens and through which the laser light passes, wherein a predetermined pattern that is able to reduce diffraction of the laser light is formed at a peripheral edge portion of each of the plurality of opening portions.

The predetermined pattern may be a pattern in which arcs or polygons having a predetermined size are continuous.

The projection lens may be a plurality of micro-lenses included in a micro-lens array that is able to divide the laser light, and the predetermined size may be equal to or less than a performance of the micro-lens array in resolution.

The projection lens may be a plurality of micro-lenses included in a micro-lens array that is able to divide the laser light, the predetermined pattern may be a sine wave or a rectangular wave, and a wavelength or an amplitude of the sine wave or the rectangular wave may be equal to or less than a performance of the micro-lens array in resolution.

Each of the plurality of opening portions may have a substantially rectangular shape, and the predetermined pattern may be formed on a peripheral edge portion of at least one of a long side and a short side of the rectangular shape.

A projection mask radiates laser light and includes a plurality of opening portions through which the laser light from the projection lens is transmitted to a predetermined region of an amorphous silicon thin film deposited on a thin film transistor, wherein a predetermined pattern that is able to reduce diffraction of the laser light is formed at a peripheral edge portion of each of the plurality of opening portions.

The predetermined pattern may be a pattern in which arcs or polygons having a predetermined size are continuous.

The projection lens may be a plurality of micro-lenses included in a micro-lens array that is able to divide the laser light, and the predetermined size may be equal to or less than a performance of the micro-lens array in resolution.

The projection lens may be a plurality of micro-lenses included in a micro-lens array that is able to divide the laser light, the predetermined pattern may be a sine wave or a rectangular wave, and a wavelength or an amplitude of the sine wave or the rectangular wave may be equal to or less than a performance of the micro-lens array in resolution.

Each of the plurality of opening portions may have a substantially rectangular shape, and the predetermined pattern may be formed on a peripheral edge portion of at least one of a long side and a short side of the rectangular shape.

A laser irradiation method includes a generation step of generating laser light, a transmission step of transmitting the laser light through a projection mask including a plurality of opening portions disposed on a projection lens and through which the laser light passes, and a projection step of irradiating a predetermined region of an amorphous silicon thin film deposited on a thin film transistor with the laser beam through a projection mask, wherein a predetermined pattern that is able to reduce diffraction of the laser light is formed at a peripheral edge portion of each of the plurality of opening portions.

A laser irradiation device, a projection mask and a laser irradiation method that can suppress a variation of characteristics in a plurality of thin film transistors included in a substrate by reducing non-uniformity in characteristics of laser light applied to a channel region and reducing a variation in a formed polysilicon thin film are provided.

### BRIEF DESCRIPTION OF THE DRAWINGS

FIG. 1 is a diagram showing a configuration of a laser irradiation device according to a first example.

FIG. 2 is a diagram showing a configuration of a thin film transistor in which a predetermined region is annealed according to the first example.

FIG. 3 is a diagram showing a configuration of a micro-lens array according to the first example.

FIG. 4 is a diagram showing a configuration of a projection mask according to the first example.

FIG. 5 is a diagram showing a configuration of an opening portion included in a projection mask.

FIG. 6 is a graph showing a state of energy of laser light in a channel region when the laser light is radiated using the projection mask shown in FIG. 5.

FIG. 7 is a diagram showing a configuration of the opening portion having a predetermined pattern capable of reducing diffraction of the laser light according to the first example.

FIG. 8 is a graph showing a state of energy of the laser light in the channel region when the laser light is radiated using the projection mask shown in FIG. 7.

FIGS. 9A to 9C are diagrams showing another configuration of the opening portion having a predetermined pattern capable of reducing diffraction of the laser light according to the first example.

FIGS. 10A and 10B are diagrams showing yet another configuration of the opening portion having a predetermined pattern capable of reducing diffraction of the laser light according to the first example.

FIG. 11 is a flowchart showing an operation configuration of the laser irradiation device according to the first example.

FIG. 12 is a diagram showing a configuration of a laser irradiation device according to a second example.

### EXPLANATION OF REFERENCES

10 Laser irradiation device
11 Laser light source
12 Coupling optical system
13 Micro-lens array
14 Laser light
15 Projection mask
150 Opening portion
17 Micro-lens
18 Projection lens
20 Thin film transistor
21 Polysilicon thin film
22 Source
23 Drain
30 Substrate

### DETAILED DESCRIPTION

Hereinafter, examples will be specifically described with reference to the accompanying drawings.

### First Example

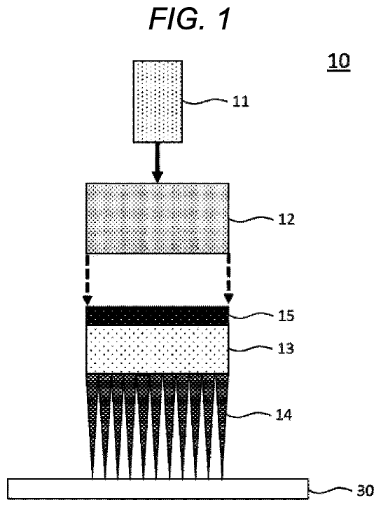

FIG. 1 is a diagram showing a configuration of a laser irradiation device 10 according to a first example.

The laser irradiation device 10 is, for example, a device in which laser light is radiated to a region in which a channel region is scheduled to be performed and an annealing treatment is performed to polycrystallize the region in which the channel region is scheduled to be formed in a manufacturing process of a semiconductor device such as a thin film transistor (TFT).

The laser irradiation device 10 is used, for example, when a thin film transistor of a pixel such as a peripheral circuit of a liquid crystal display device is formed. When such a thin film transistor is formed, first, a gate electrode made of a metal film, made of, for example, Al is patterned on a substrate 30 by sputtering. Then, a gate insulating film made of a SiN film is formed on the entire surface of the substrate 30 by a low-temperature plasma chemical vapor deposition (CVD) method. Then, an amorphous silicon thin film is formed on the gate insulating film by, for example, a plasma CVD method. That is, the amorphous silicon thin film is formed (deposited) on the entire surface of the substrate 30. Finally, a silicon dioxide (SiO₂) film is formed on the amorphous silicon thin film. Additionally, a predetermined region on a gate electrode of the amorphous silicon thin film (a region to be the channel region in the thin film transistor 20) is irradiated with laser light 14 by the laser irradiation device 10 shown in FIG. 1 and is annealed and, thus, the predetermined region is polycrystallized into polysilicon. The substrate 30 is, for example, a glass substrate, but the substrate 30 may not necessarily be a glass material and may be a substrate of any material such as a resin substrate formed of a material such as a resin.

As shown in FIG. 1, in the laser irradiation device 10, a beam system of the laser light emitted from a laser light source 11 is expanded by a coupling optical system 12, and a luminance distribution is made uniform. The laser light source 11 is, for example, an excimer laser that emits laser light having a wavelength of 308 nm or 248 nm using a predetermined repeating cycle. Also, the wavelength is not limited to this example and may be any wavelength.

Further, the laser light passes through a plurality of opening portions of a projection mask 15 provided on the micro-lens array 13, is divided into a plurality of laser light beams 14, and transmitted to a predetermined region of the amorphous silicon thin film coated on the substrate 30. When the predetermined region of the amorphous silicon thin film coated on the substrate 30 is irradiated with the laser light 14, the amorphous silicon thin film is instantaneously heated and melted and becomes a polysilicon thin film.

Since the polysilicon thin film has a higher electron mobility than that of the amorphous silicon thin film, a current can easily flow therethrough, and the polysilicon thin film can be used for a channel region in a thin film transistor that electrically connects a source to a drain.

In the example of FIG. 1, although an example in which the micro-lens array 13 is used is shown, the micro-lens array 13 does not necessarily need to be used, and the laser light 14 may be radiated using one projection lens. Also, in the first example, when the substrate 30 is irradiated with the laser light 14 using the micro-lens array 13 will be described as an example.

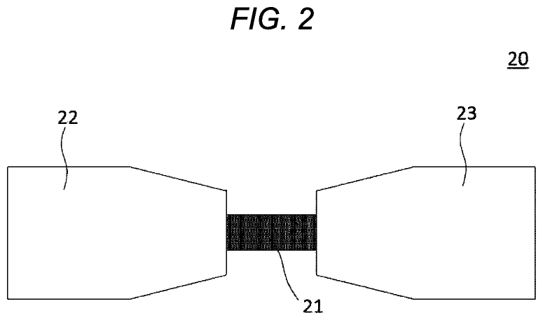

FIG. 2 is a diagram showing a configuration of the thin film transistor 20 in which a predetermined region is annealed in the first example. The thin film transistor 20 is formed by first forming a polysilicon thin film 21 and then providing a source 22 and a drain 23 at both ends of the formed polysilicon thin film 21 (that is, the channel region). In the thin film transistor shown in FIG. 2, as a result of the laser annealing, at least one polysilicon thin film 21 is formed between the source 22 and the drain 23. As shown in FIG. 2, when the source 22 and the drain 23 are connected by the polysilicon thin film 21 having high electron mobility, the source 22 and the drain 23 are electrically connected to each other and can serve as the thin film transistor 20.

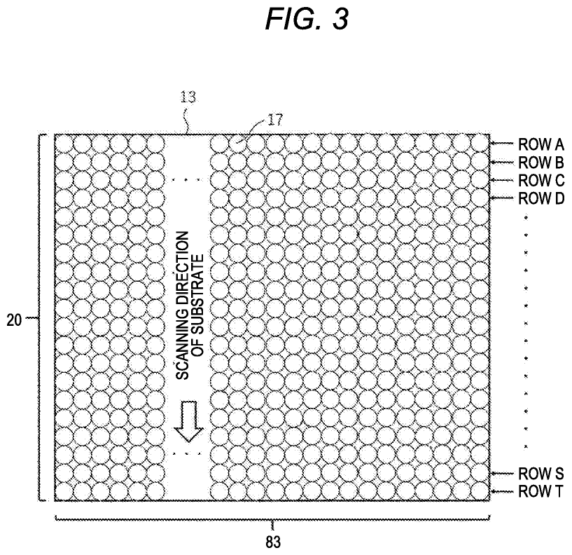

FIG. 3 is a diagram showing a configuration of the micro-lens array 13 according to the first example. As shown in FIG. 3, the micro-lens array 13 includes a plurality of microlenses 17. One column of the micro-lens array 13 (one column in a direction parallel to a moving direction of the substrate) includes, for example, twenty micro-lenses 17. In addition, one row of the micro-lens array 13 (one row in a direction perpendicular to the moving direction of the substrate) includes, for example, eighty-three micro-lenses 17. These numbers are merely examples, and the number of micro-lenses 17 included in one row or one column of the microlens array 13 may be any number.

The laser irradiation device 10 irradiates a predetermined region on the substrate 30 with the laser light 14 sequentially using the plurality of micro-lenses 17 included in the microlens array 13. A situation in which a laser beam is radiated on a certain predetermined region (it is defined as a predetermined region A, and the predetermined region A is not shown) among a plurality of predetermined regions on the substrate 30 will be described. The predetermined region A is a region in which the laser annealing is performed using the micro-lenses 17 in the leftmost column of the micro-lens array 13. Each of the plurality of predetermined regions on the substrate 30 is subjected to the laser annealing by the micro-lenses 17 included in any one (one column among 83 columns in the example of FIG. 3) of the plurality of columns (83 columns in the example of FIG. 3) of the micro-lens array 13.

First, the predetermined region A is subjected to the laser annealing by the micro-lens 17 in a T row of the leftmost column of the micro-lens array 13. Thereafter, the substrate 30 is moved by a predetermined distance. The predetermined distance is, for example, an interval between the adjacent micro-lenses 17 (or a distance corresponding to the interval). After the movement of the substrate 30, the predetermined region A is laser-annealed by the micro-lens 17 in an S row in the leftmost column of the micro-lens array 13. The predetermined region A is irradiated with the laser light 14 by the 20 micro-lenses 17 included in one column of the microlens array 13 (one column in the moving direction of the substrate) by repeating this process. That is, one predetermined region is irradiated with the laser light 14 20 times (20 shots).

In this way, it is possible to reliably perform a laser annealing treatment on the predetermined region and to grow a crystal of the polysilicon thin film by irradiating one predetermined region with the laser light 14 20 times (20 shots).

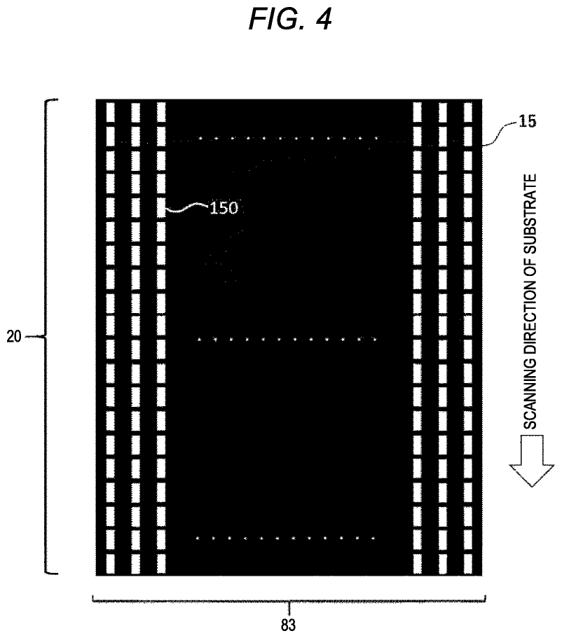

FIG. 4 is a diagram showing a configuration of the projection mask 15 according to the first example. As shown in FIG. 4, the projection mask 15 includes a plurality of opening portions 150. Positions of the plurality of opening portions 150 included in the projection mask 15 correspond to positions of the micro-lenses 17 included in the micro-lens array 13 shown in FIG. 3. Therefore, as shown in FIG. 4, the number of the opening portions 150 included in one column of the projection mask 15 (one column in the moving direction of the substrate) is 20, and the number of the opening portions 150 included in one row of the projection mask 15 is 83. The number of the opening portions 150 may be any number.

As shown in FIG. 4, each of the plurality of opening portions 150 included in the projection mask 15 has a substantially rectangular shape. Each of the plurality of opening portions 150 corresponds to a shape of the predetermined region on the substrate 30, and when the shape of the predetermined region is substantially rectangular, the shape of each of the plurality of opening portions 150 is also substantially rectangular. The shape of each of the plurality of opening portions 150 does not necessarily have to be substantially rectangular and may be any shape as long as it corresponds to the shape of the predetermined region.

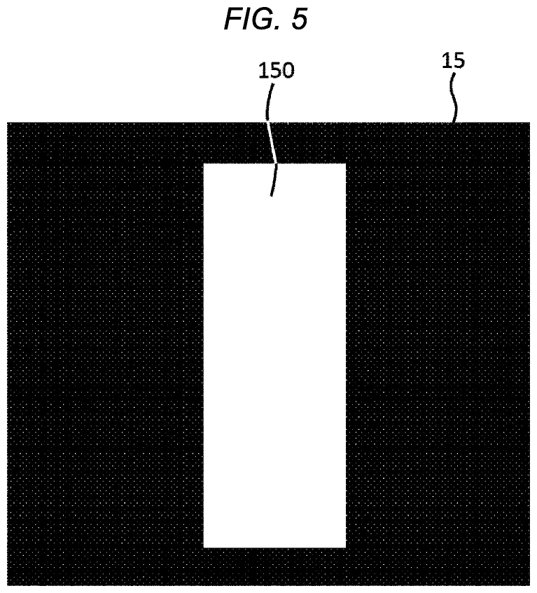

FIG. 5 is a configuration of the opening portion 150 included in the projection mask 15. The opening portion 150 shown in FIG. 5 is an opening portion 150 wherein “a predetermined pattern which can reduce diffraction of the laser light” is not formed on a peripheral edge portion thereof.

As shown in FIG. 5, the projection mask 15 includes the opening portion 150 through which the laser light passes, and a laser beam masking region (a region other than the opening portion) which masks laser light. The laser light passes through the opening portion 150 included in the projection mask and is radiated to a predetermined region on the substrate 30. A length of a long side of the opening portion 150 is about 100 μm, and a length of a short side is about 50 μm. However, these lengths are examples, and any lengths may be used. The microlens array 13 irradiates the substrate 30 with the laser beam pattern projected through the opening portion 150 of the projection mask 15 reduced to, for example, one fifth. That is, the laser light having passed through the opening portion 150 is radiated on the substrate 30 in a range of one fifth of the laser beam pattern through the opening portion 150. That is, the predetermined region on the substrate 30 has a long side length of about 20 μm and a short side length of about 10 μm. Also, a reduction ratio of the micro-lens array 13 is not limited to one fifth and may be any reduction ratio.

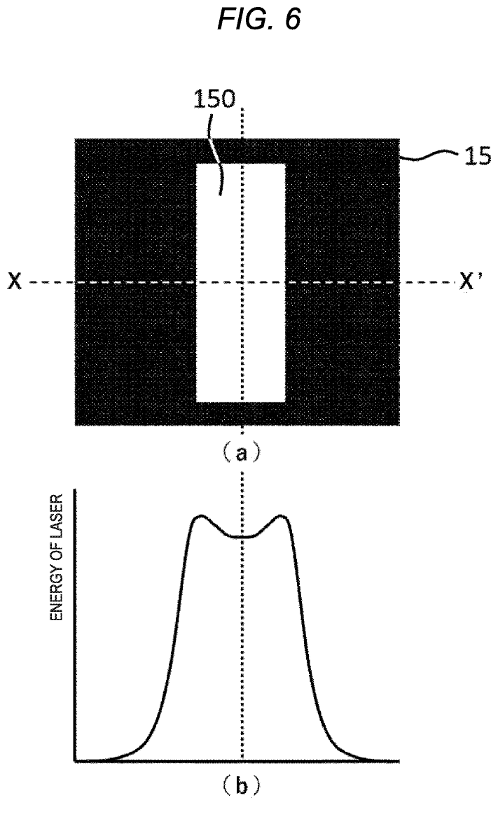

FIG. 6 is a graph showing a state of energy of the laser light 14 when the laser light 14 is radiated using the projection mask 15 shown in FIG. 5. The graph of (b) of FIG. 6 shows the state of energy at a position corresponding to a straight line X-X′ parallel to the short side of the opening portion 150 of the projection mask of (a) of FIG. 6. In the graph of FIG. 6, a horizontal axis is the position, and a vertical axis is the energy of the laser light 14. The example of FIG. 6 is merely an example, and the state of the energy of the laser light 14 may change according to irradiation energy of the laser light 14, a size of the opening portion 150 and the like.

As shown in (b) of FIG. 6, when irradiation is performed on a portion to be the channel region, the energy of the laser light 14 which has passed through a peripheral edge portion (an edge portion) of the opening portion 150 is higher than that of the laser light 14 which has passed through other portions. This is because the laser light 14 is diffracted at the peripheral edge portion of the opening portion 150. As described above, when the energy of the radiated laser light 14 is high, the amorphous silicon thin film on the substrate 30 becomes a polysilicon thin film, and a speed of re-crystallization of the polysilicon thin film increases. Thus, the speed of re-crystallization (crystallization of the polysilicon thin film) of a portion (a peripheral edge portion of the predetermined region) corresponding to the peripheral edge portion of the opening portion 150 in the predetermined region on the substrate 30 is higher than that of other portions (a center portion of the predetermined region and the like).

Accordingly, in the predetermined region (the portion to be the channel region), a degree of crystallization of the polysilicon crystal becomes non-uniform, and characteristics of the polysilicon thin film are not uniform in the predetermined region. Therefore, characteristics of the finally formed thin film transistor will be unstable. As a result, there is a problem that display unevenness occurs in the liquid crystal formed using the substrate.

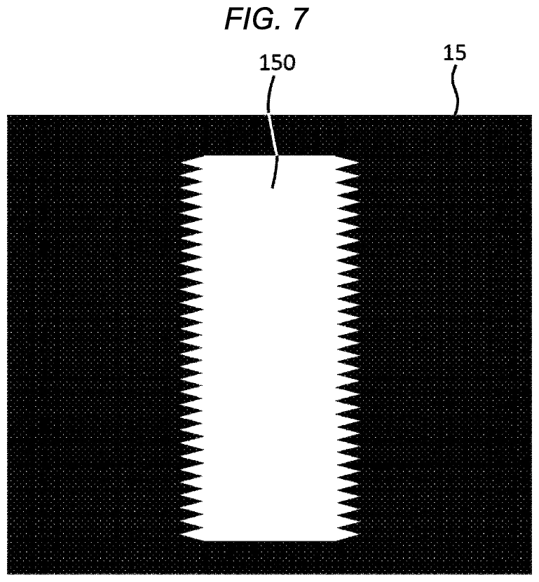

Therefore, as shown in FIG. 7, in the opening portion 150 of the first example, a predetermined pattern that can reduce the diffraction of the laser light 14 is provided on the peripheral edge portion of the opening portion 150. The predetermined pattern is, for example, a pattern in which arcs or polygons having a predetermined size are continuous. The polygon may be any polygon such as a triangle or a quadrangle.

The predetermined size is preferably equal to or less than a performance (resolution) of the micro-lenses 17 included in the micro-lens array 13. This is because when the arc or polygon included in the predetermined pattern is larger than the performance (resolution) of the micro-lenses 17, the irradiation of the laser light 14 causes the predetermined pattern to be reproduced on the substrate 30. However, the predetermined size does not necessarily need to be equal to or less than the performance (resolution) of the micro-lenses 17 and may be larger than the performance (resolution).

The performance (resolution) of the micro-lens 17 is indicated by, for example, a minimum value of a size that can be processed using the laser light 14 having passed through the micro-lenses 17. The performance (resolution) of the micro-lenses 17 included in the micro-lens array 13 is, for example, 2 μm. In this example, the predetermined pattern is preferably a pattern in which arcs or polygons having a size of 2 μm or less are continuous. The performance (resolution) of the micro-lenses 17 is not limited to 2 μm and may have any value.

In addition, the predetermined pattern does not necessarily need to have the same polygons which are continuous, and the predetermined pattern may include a plurality of different polygons.

FIG. 7 is a diagram showing a configuration of the opening portion 150 having a predetermined pattern which can reduce the diffraction of the laser light 14 according to the first example. As shown in FIG. 7, a predetermined pattern in which triangles having a predetermined size are continuous is provided at the peripheral edge portion of the opening portion 150. Also, the size of the triangle included in the predetermined pattern is preferably smaller than the performance (resolution) of the micro-lenses 17.

As shown in FIG. 7, when the predetermined pattern having triangles is provided on the peripheral edge portion of the opening portion 150, the laser light 14 diffracted by one side of one adjacent triangle and the laser light 14 diffracted by one side of the other triangle interfere with each other and cancel each other out at the peripheral edge portion. Therefore, the laser light 14 diffracted by the peripheral edge portion of the opening portion 150 is reduced.

In the example of FIG. 7, a predetermined pattern provided on one side of the peripheral edge portion of the opening portion 150 (for example, a left peripheral edge portion of the long side of the opening portion 150 shown in FIG. 7) and a predetermined pattern provided on the other side of the peripheral edge portion of the opening portion 150 (for example, a right peripheral edge portion of the long side of the opening portion 150 shown in FIG. 7) may have the same phase or may have opposite phases. The phases of the two predetermined patterns may be shifted from each other by an arbitrary angle.

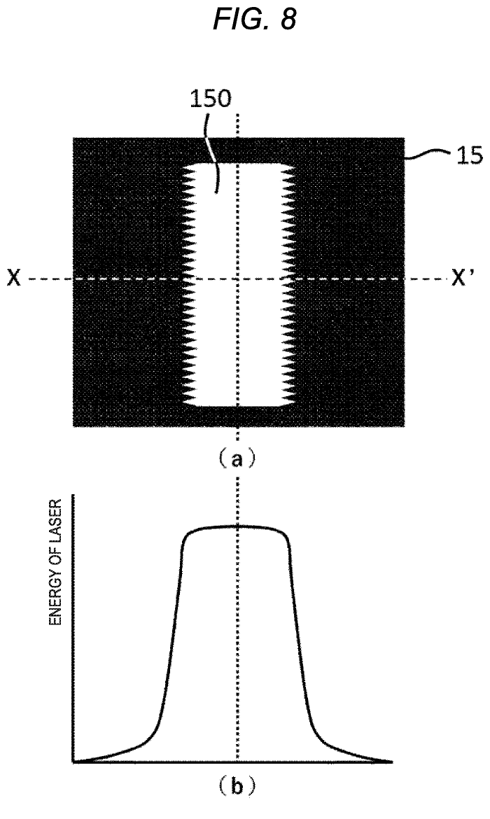

FIG. 8 is a graph showing a state of the energy of the laser light 14 in the channel region when the laser light 14 is radiated using the projection mask 15 illustrated in FIG. 7. The graph of (b) in the lower portion of FIG. 8 shows the state of the energy at a position corresponding to a straight line X-X′ parallel to the short side of the opening portion 150 of the projection mask of (a) in the upper portion of FIG. 8 in the channel region. In the graph of FIG. 8, a horizontal axis is the position in the channel region, and a vertical axis is the energy of the laser light 14 (the energy in the channel region). The example in FIG. 8 is also just an example as in FIG. 6, and the state of the energy of the laser light 14 in the channel region can change according to irradiation energy of the laser light 14, a size of the opening portion 150 and the like.

As shown in (b) of FIG. 8, in the channel region, the energy of the laser light 14 which has passed through the opening portion 150 is uniform in any portion. In the example of (b) of FIG. 6, while the irradiation energy of the laser light 14 at the peripheral edge portion of the opening portion 150 is larger than that at the other portions, in the example of (b) of FIG. 8, the irradiation energy of the laser light 14 is substantially uniform between the peripheral edge portion of the opening portion 150 and the other portions without a large difference. This is because, in the example of FIG. 8, the diffraction of the laser light 14 is reduced by the predetermined pattern provided in the peripheral edge portion of the opening portion 150.

As described above, when the irradiation energy of the laser light 14 in the predetermined region (the portion to be the channel region) is uniform, the degree of crystallization of the polysilicon crystal becomes uniform in the predetermined region, and the characteristics of the polysilicon thin film become substantially uniform. Thus, a variation in characteristics of the thin film transistor finally formed can be suppressed and, as a result, display unevenness can be suppressed in the liquid crystal formed using the substrate.

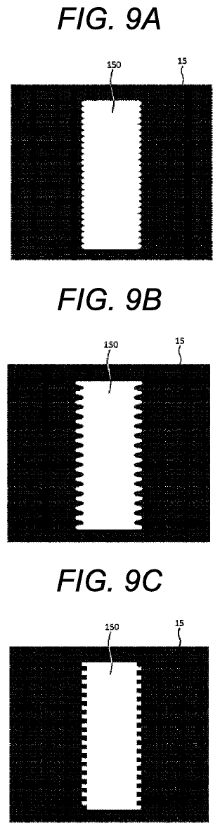

FIGS. 9A to 9C are diagrams each showing another configuration of the opening portion 150 having the predetermined pattern that can reduce the diffraction of the laser light 14 according to the first example. As described above, the predetermined pattern provided on the peripheral edge portion of the opening portion 150 may be a pattern in which arcs having a predetermined size are continuous as shown in FIG. 9A. The size of the arcs included in the predetermined pattern is preferably equal to or smaller than the performance (resolution) of the micro-lenses 17.

Further, the predetermined pattern may be, for example, a sine wave shown in FIG. 9B or a rectangular wave shown in FIG. 9C. An amplitude of the sine wave or the rectangular wave may be any amplitude, and a wavelength of the sine wave or the rectangular wave may be any wavelength. The amplitude or the wavelength of the sine wave or the rectangular wave is preferably equal to or smaller than the performance (resolution) of the micro-lenses 17. However, the amplitude or the wavelength of the sine wave or the rectangular wave need not necessarily to be equal to or smaller than the performance (resolution) of the micro-lenses 17 and may be larger than the performance (resolution). Further, in the sine wave of FIG. 9B and the rectangular wave of FIG. 9C, the waveform provided at one side of the peripheral edge portion of the opening portion 150 and the waveform provided at the other side of the peripheral edge portion of the opening portion 150 may have the same phases, may have opposite phases and may be shifted from each other by an arbitrary angle.

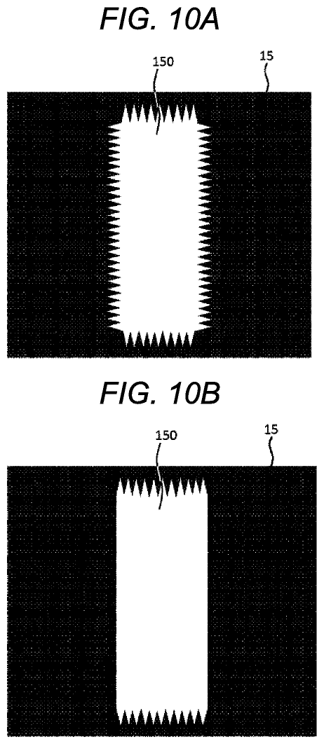

FIGS. 10A and 10B are diagrams each showing yet another configuration of the opening portion 150 having the predetermined pattern that can reduce the diffraction of the laser light 14 according to the first example. As shown in FIG. 10A, the predetermined pattern provided on the peripheral edge portion of the opening portion 150 may be provided on the peripheral edge portion of the short side in addition to the long side of the opening portion 150. Thus, the diffraction of the laser light 14 can be reduced even at the peripheral edge portion of the short side of the opening portion 150, and the irradiation energy of the laser light 14 can be made uniform. Further, as shown in FIG. 10B, the predetermined pattern provided on the peripheral edge portion of the opening portion 150 may be provided only on the peripheral edge portion of the opening portion 150. That is, the predetermined pattern may be formed on at least one of the long side and the short side of the peripheral edge portion of the opening portion 150.

Also, the predetermined pattern provided on one side of the peripheral edge portion of the short side of the opening portion 150 and the predetermined pattern provided on the other side thereof may have the same phases, may have opposite phases and may be shifted from each other by an arbitrary angle. Furthermore, the predetermined pattern provided on the peripheral edge portion of the short side of the opening portion 150 is not limited to the examples of FIGS. 10A and 10B, and may be continuous arcs or polygons, a sine wave, a rectangular wave, or a combination of a plurality of polygons.

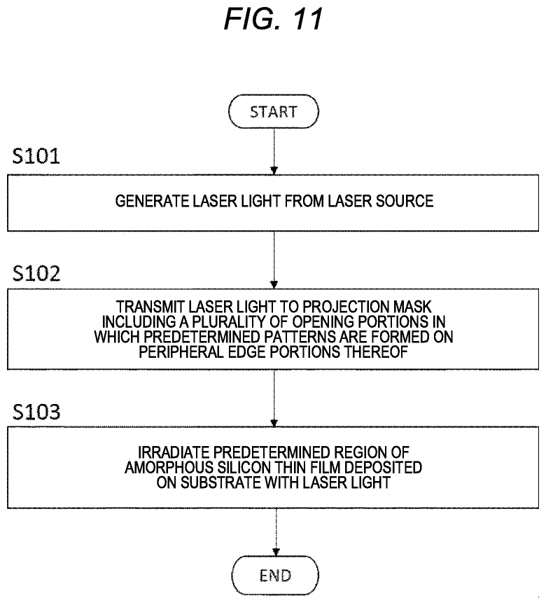

Next, a method of radiating the laser light with the laser irradiation device 10 will be described. FIG. 11 is a flowchart showing an operation configuration of the laser irradiation device 10 according to the first example.

As shown in FIG. 11, first, the laser light source 11 of the laser irradiation device 10 generates laser light (S101). Subsequently, the generated laser light passes through the projection mask 15 including the plurality of opening portions 150 disposed on the micro-lens array 13 and through which the laser light passes (S102). A predetermined pattern that can reduce the diffraction of the laser light is formed on the peripheral edge portion of each of the plurality of opening portions 150. Finally, the micro-lens array 13 irradiates a predetermined region of the amorphous silicon thin film deposited on the substrate 30 with the laser light (S103).

Also, the substrate 30 moves by a predetermined distance whenever the laser light 14 is radiated by one micro-lens 17. The predetermined distance is a length (for example, “H”) between adjacent predetermined regions (the channel regions). The laser irradiation device 10 may stop the radiation of the laser light 14 or may continue the radiation of the laser light 14 while the substrate 30 moves by the predetermined distance.

As described above, in the first example, non-uniformity of the irradiation energy of the laser light 14 is eliminated by providing the predetermined pattern that can reduce the diffraction of the laser light 14 at the peripheral edge portion of each of the plurality of opening portions 150 of the projection mask 15. Therefore, the degree of crystallization of the polysilicon crystal in the predetermined region on the substrate 30 becomes uniform, and the characteristics of the polysilicon thin film become substantially uniform. As a result, a variation in the characteristics of the plurality of thin film transistors formed on the substrate 30 can be suppressed, and the display unevenness can be prevented from occurring in the liquid crystal formed using the substrate 30.

### Second Example

A second example is an example in which laser annealing is performed using one projection lens 18 instead of the micro-lens array 13.

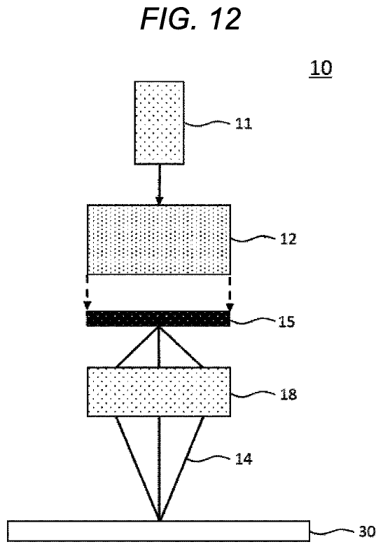

FIG. 12 is a diagram showing a configuration of a laser irradiation device 10 according to a second example. As shown in FIG. 12, the laser irradiation device 10 according to the second example includes a laser light source 11, a coupling optical system 12, a projection mask 15 and a projection lens 18. Since the laser light source 11 and the coupling optical system 12 have the same configuration as the laser light source 11 and the coupling optical system 12 in the first example shown in FIG. 1, detailed description thereof will be omitted.

The laser light passes through the plurality of opening portions of the projection mask 15 and is radiated by the projection lens 18 to a predetermined region of the amorphous silicon thin film coated on the substrate 30. As a result, the predetermined region of the amorphous silicon thin film is instantaneously heated and melted, and a part of the amorphous silicon thin film becomes a polysilicon thin film.

In the second example, the projection mask 15 is a projection mask 15 in which a predetermined pattern which can reduce the diffraction of the laser light is provided on the peripheral edge portion of the opening portion, as shown in FIGS. 7, 9 and 10. The predetermined pattern may be, for example, a pattern in which triangles having a predetermined size are continuous as shown in FIG. 7 or a pattern in which arcs having a predetermined size are continuous as shown in FIG. 9A. The size of the triangles or the arcs included in the predetermined pattern is preferably smaller than the performance (resolution) of the projection lens 18. Further, the predetermined pattern may be, for example, a sine wave shown in FIG. 9B or a rectangular wave shown in FIG. 9C. Also, an amplitude or a wavelength (or a half wavelength) of the sine wave or the rectangular wave is preferably equal to or less than the performance (resolution) of the projection lens 18.

Also, in the second example, the laser irradiation device 10 radiates the laser light 14 at a predetermined period, moves the substrate 30 during a time when the laser light 14 is not radiated and radiates the laser light 14 to the next amorphous silicon thin film.

When the projection lens 18 is used, a region irradiated with the laser light 14 is converted by a magnification of the optical system of the projection lens 18. That is, the predetermined region on the substrate 30 in which the laser annealing is performed is a region in which the opening portion 150 included in the projection mask 15 is converted by the magnification of the optical system of the projection lens 18. The opening portion 150 of the projection mask 15 is converted by the magnification of the optical system of the projection lens 18, and the predetermined region on the substrate 30 is subjected to the laser annealing. Since the magnification of the optical system of the projection lens 18 is about twice, the opening portion 150 of the projection mask 15 is multiplied by about ½ (0.5), and the predetermined region (a portion to be a channel region) of the substrate 30 is subjected to the laser annealing. Accordingly, it is necessary to set the size of the opening portion 150 on the basis of the magnification of the optical system of the projection lens 18 with reference to the size of the desired predetermined region on the substrate 30. The magnification of the optical system of the projection lens 18 is not limited to about 2 times and may be any magnification. For example, when the magnification of the optical system of the projection lens 18 is four times, the opening portion 150 of the projection mask 15 is multiplied by about ¼ (0.25), and the predetermined region of the substrate 30 is subjected to the laser annealing.

When the projection lens 18 forms an inverted image, a reduced image of the opening portion 150 of the projection mask 15 radiated on the substrate 30 has a pattern rotated by 180 degrees around an optical axis of a lens of the projection lens 18. On the other hand, when the projection lens 18 forms an upright image, the reduced image of the opening portion 150 of the projection mask 15 radiated on the substrate 30 is the same as the opening portion 150 of the projection mask 15. In the example of FIG. 12, since the projection lens 18 which forms an upright image is used, the opening portion 150 of the projection mask 15 is reduced on the substrate 30 as it is.

As described above, in the second example, when the projection lens 18 is used, the non-uniformity of the irradiation energy of the laser light 14 is eliminated by providing the predetermined pattern that can reduce the diffraction of the laser light 14 at the peripheral edge portion of each of the plurality of opening portions 150 included in the projection mask 15. Therefore, the degree of crystallization of the polysilicon crystal in the predetermined region on the substrate 30 becomes uniform, and the characteristics of the polysilicon thin film become substantially uniform. As a result, the variation in the characteristics of the plurality of thin film transistors formed on the substrate 30 can be suppressed, and the display unevenness can be prevented from occurring in the liquid crystal formed using the substrate 30.

In the above description, when there is a description such as “vertical,” “parallel,” “plane” and the like, these descriptions do not have strict meanings. That is, “vertical,” “parallel” and “plane” allow a tolerance or error in design, manufacturing and the like, and mean “substantially vertical,” “substantially parallel” and “substantially plane.” A tolerance or error refers to amounts within a range which does not deviate from the configuration, operations and desired effects.

In addition, in the above description, when there is a description such as “same,” “equal,” “different” or the like in appearance dimensions or sizes, the description is not strictly meaning. That is, “same,” “equal” and “different” allow a tolerance or error in design, manufacturing and the like, and mean “substantially the same,” “substantially equal” and “substantially different.” The tolerance or error means a unit within a range that does not deviate from the configuration, operations and desired effects.

Although this disclosure has been described with reference to the drawings and examples, those skilled in the art can easily make various changes and modifications based on the disclosure. Therefore, the changes and modifications are included in the scope of this disclosure. For example, functions and the like included in each means, each step and the like can be rearranged not to be logically inconsistent, and a plurality of means, steps and the like can be combined into one or divided. Further, the configurations described in the above examples may be combined as appropriate.

1-11. (canceled)

12. A laser irradiation device comprising:
a light source that generates laser light;
a projection lens that radiates the laser light to a predetermined region of an amorphous silicon thin film deposited on a thin film transistor; and
a projection mask including a plurality of opening portions disposed on the projection lens and through which the laser light passes,
wherein a predetermined pattern that is able to reduce diffraction of the laser light is formed at a peripheral edge portion of each of the plurality of opening portions.

13. The laser irradiation device according to claim 12, wherein the predetermined pattern is a pattern in which arcs or polygons having a predetermined size are continuous.

14. The laser irradiation device according to claim 13, wherein:
the projection lens is a plurality of micro-lenses included in a micro-lens array that is able to divide the laser light, and
the predetermined size is equal to or less than a performance of the micro-lens array.

15. The laser irradiation device according to claim 12, wherein:
the projection lens is a plurality of micro-lenses included in a micro-lens array that is able to divide the laser light,
the predetermined pattern is a sine wave or a rectangular wave, and
a wavelength or an amplitude of the sine wave or the rectangular wave is equal to or less than a performance of the micro-lens array in resolution.

16. The laser irradiation device according to claim 12, wherein each of the plurality of opening portions has a substantially rectangular shape, and the predetermined pattern is formed on a peripheral edge portion of at least one of a long side and a short side of the rectangular shape.

17. A projection mask disposed on a projection lens that radiates laser light, comprising:
a plurality of opening portions through which the laser light from the projection lens is transmitted to a predetermined region of an amorphous silicon thin film deposited on a thin film transistor,
wherein a predetermined pattern that is able to reduce diffraction of the laser light is formed at a peripheral edge portion of each of the plurality of opening portions.

18. The projection mask according to claim 17, wherein the predetermined pattern is a pattern in which arcs or polygons having a predetermined size are continuous.

19. The projection mask according to claim 18, wherein:
the projection lens is a plurality of micro-lenses included in a micro-lens array that is able to divide the laser light, and
the predetermined size is equal to or less than a performance of the micro-lens array in resolution.

20. The projection mask according to claim 17, wherein:
the projection lens is a plurality of micro-lenses included in a micro-lens array that is able to divide the laser light,
the predetermined pattern is a sine wave or a rectangular wave, and
a wavelength or an amplitude of the sine wave or the rectangular wave is equal to or less than a performance of the micro-lens array in resolution.

21. The projection mask according to claim 17, wherein each of the plurality of opening portions has a substantially rectangular shape, and the predetermined pattern is formed on a peripheral edge portion of at least one of a long side and a short side of the rectangular shape.

22. A laser irradiation method comprising:
generating laser light;
transmitting the laser light through a projection mask including a plurality of opening portions disposed on a projection lens and through which the laser light passes; and
irradiating a predetermined region of an amorphous silicon thin film deposited on a thin film transistor with the laser light through the projection mask,
wherein a predetermined pattern that is able to reduce diffraction of the laser light is formed at a peripheral edge portion of each of the plurality of opening portions.
